(19) United States
(12) Patent Application Publication
(10) Pub. No.: US 2014/0345922 A1
(43) Pub. Date: Nov. 27, 2014

(54) INKJET PRINTED ELECTRONIC DEVICE

(71) Applicant: Charles E. Romano, JR., Wisconsin Rapids, WI (US)

(72) Inventor: Charles E. Romano, JR., Wisconsin Rapids, WI (US)

(73) Assignee: NewPage Corporation, Miamisburg, OH (US)

(21) Appl. No.: 14/456,186

(22) Filed: Aug. 11, 2014

Related U.S. Application Data
(63) Continuation-in-part of application No. 14/309,201, filed on Jun. 19, 2014.
Application No. 14/309,201 is a continuation-in-part of application No. 13/326,915, filed on Dec. 15, 2011, now Pat. No. 8,821,997.
(60) Provisional application No. 61/423,408, filed on Dec. 15, 2010.

(51) Int. Cl. H05K 1/09; H05K 3/46; H05K 1/03

(52) U.S. Cl. CPC H05K 1/095; H05K 1/0386; H05K 3/4644; H05K 2201/09218
USPC 174/257; 427/97.3

(57) ABSTRACT

A printed electronic device and a coating composition for forming a printed electronic device comprising an ink jet-receptive coating on a paper substrate.

### CROSS REFERENCE TO RELATED APPLICATIONS

This application is a continuation-in-part of U.S. application Ser. No. 14/309,201 filed Jun. 19, 2014, which in turn is a continuation-in-part of U.S. application Ser. No. 13/326,915 filed Dec. 15, 2011, which claims the benefit of U.S. Provisional Application Ser. No. 61/423,408 filed Dec. 15, 2010, the entire contents of which are hereby incorporated by reference.

### BACKGROUND

Ink jet technologies have been used to form circuitry. These ink jet technologies include a variety of methods. Some involve ink jetting of a precursor material which aids in deposition of conductive metals. Other methods involve printing of conductive inks onto a substrate.

The present application relates to a printed electronic device and a coating composition for forming an ink jet recording medium for making a printed electronic device by application of an electrically conductive ink to a recording medium. More specifically, the resulting recording medium is particularly useful as a recording medium carrying an electrically conductive circuit.

Printed electronics are typically made by printing the electronic circuit or other component or device on a substrate using an electrically conductive metal-containing ink. The inks typically contain silver particles, and occasionally copper particles, other metallic particles, and/or conductive polymers.

### SUMMARY

This application describes a printed electronic device and a coating composition for forming a printed electronic device. In accordance with one aspect of the present invention, a ink jet recording medium is disclosed to which an electrically conductive ink is applied in the form of an electric circuit. The recording medium comprises an ink jet-receptive coating on a paper substrate. The ink jet-receptive coating contains a synergistic combination of pigments, binder and optionally, in one embodiment, a supplemental pigment and/or a plastic pigment. In another embodiment, the ink receptive coating optionally includes a multivalent salt. In another embodiment a cationic polymer may be used in place of or in combination with the secondary pigment.

In one embodiment the primary pigment may be a precipitated or a finely ground, anionic pigment with a narrow particle size distribution, such as calcium carbonate. In one embodiment, the primary pigment is a precipitated calcium carbonate (e.g., aragonite). In a particular embodiment, the precipitated calcium carbonate has a particle size distribution where at least 96% of the particles by weight have a particle size less than 2 microns. In another embodiment the primary pigment is a fine ground calcium carbonate. In one embodiment the secondary pigment may be a cationic pigment, for example, the secondary pigment may be a cationic, grit-free pigment having an average particle size of 3 microns or less. The coating also includes up to 17 weight % of a hydrophilic styrene-butadiene latex binder based on the weight of the dry pigments and a co-binder. This coating is described in U.S. Pat. No. 7,803,224 to Schliesman which is herein incorporated by reference in its entirety. In another embodiment, the composition contains aragonite, a multi-valent salt such as calcium chloride, and a calcium stable latex binder, as disclosed in U.S. Published Application 2012/0154502 which is incorporated herein by reference. In another embodiment, the coating includes a fine ground carbonate, a multivalent salt, and a calcium stable latex as disclosed in U.S. Pat. No. 8,727,528 which is incorporated herein by reference.

Aragonite is a particularly useful precipitated calcium carbonate that differs from other forms of calcium carbonate in both particle shape and size distribution. It is particularly useful as the primary pigment. Aragonite has a needle-like structure and a narrow particle size distribution making it particularly suitable as the primary pigment. While not wishing to be bound by theory, it is believed that the structure discourages tight particle packing of the pigment and provides the porosity needed for good absorption of the ink vehicle. Use of the aragonite form produces a surface on the treated paper having a controlled porosity as disclosed in U.S. Pat. No. 7,803,224 is incorporated herein by reference for aragonite coating compositions useful herein.

Another embodiment is a process for forming an electronic device which comprises the steps of applying a pattern of a conductive ink by means of an ink jet printing head to the surface of an ink jet recording layer or medium as described herein to form an electric circuit.

### DETAILED DESCRIPTION

U.S. Published Application 2013/0033810 to Crain is incorporated herein by reference in its entirety for its disclosure of printed electronics and electrically conductive inks applied by ink jet printing.

In one embodiment, the present invention provides a method of forming a conductive path or circuit on a substrate comprising the steps of providing conductive particulates, a liquid vehicle, and a substrate including an ink receptive coating; forming a suspension comprising the liquid vehicle and the particulate conductive material; jetting from an ink jet a predetermined pattern of the suspension onto the ink-receptive coating; and heating the substrate with the suspension ink jetted thereon to a temperature wherein the conductive particulates are bound and adhere to the substrate and provide the conductive path.

In one embodiment, the coating for producing the ink receptive coating includes a primary pigment, a secondary pigment, and a binder. In one embodiment the receptive coating may additionally include an optional supplemental pigment. In another embodiment the receptive coating may additionally include an optional plastic pigment. The primary pigment may be a precipitated or a finely ground, anionic pigment with a narrow particle size distribution such as calcium carbonate. In one embodiment the secondary pigment may be a cationic pigment. In another embodiment a cationic polymer may be used in place of or in combination with the secondary pigment. In another embodiment, the coating for producing the ink receptive coating includes a primary pigment, a multivalent salt, an optional supplemental pigment, and a binder that is calcium stable. The multivalent salt may be used alone or in combination with the secondary pigment. Further, the coating includes a binder and optionally a co-binder. Pigments typically comprise the largest portion of the coating composition on a dry weight basis. Unless otherwise noted, amounts of component materials are expressed in terms of component parts per 100 parts of total pigment on a weight basis.

In one embodiment described in U.S. Pat. No. 8,727,528 to Romano, the primary component of the coating may be a fine pigment having an average particle size (d50) of less than 1 micron, more particularly from about 0.4 to 0.8 and still more particularly from about 0.5 to 0.8 microns. In accordance with certain embodiments, the primary pigment may have a particle size distribution with a d98 of about 0.7 to 5 microns, more particularly about 2 to 3.5 microns. The one micron percentage may be about 60 to 80%, more particularly about 35 to 75%. Primary pigments that are particularly useful may have a BET surface area in the range from about 5-20, more particularly about 8-12 m²/g. In accordance with certain embodiments, the primary pigment may be at least 35 parts, more particularly from about 40 to about 90 parts, and still more particularly from about 45 to about 85 parts, per 100 parts total pigment by weight. A combination of pigments may be utilized in providing the primary pigment of the composition.

In another embodiment, the ink jet-receptive coating comprises a primary pigment having an average particle size of less than 1 micron; a secondary pigment having an average particle size of about 3 to 5 microns; a multivalent salt and a binder wherein said binder is present in an amount from about 2 to 15 parts by weight based on 100 parts total pigments. In another embodiment the composition additionally contains a multivalent metal salt. This embodiment is disclosed in U.S. Pat. No. 8,727,528 to Romano.

Calcium carbonate is useful as the primary pigment in any form, including aragonite, calcite or mixtures thereof. Calcium carbonate, when present as the primary pigment, typically makes up 35-85 parts of the coating pigment on a dry weight basis. In certain embodiments, the calcium carbonate may be from about 60 to 76 parts of the pigment weight. Aragonite is a particularly useful calcium carbonate. An advantage to using aragonite as the primary pigment is that the porous structure of the coating better withstands calendering to give it a gloss finish. A particularly useful aragonite is Specialty Minerals OPACARB A40 pigment (Specialty Minerals, Inc., Bethlehem, Pa.). A40 has a particle size distribution where 99% of the particles have a diameter of from about 0.1 to about 1.1 microns.

For the primary pigment, an alternate calcium carbonate having a narrow particle size distribution such as OMYA CoverCarb 85, OMYA CoverCarb 90, or OMYA Hydrocarb HP ground calcite calcium carbonate (OMYA AG, Oftringen, Switzerland) may be used. It provides the porous structure for successful ink absorption but less paper gloss development. This calcium carbonate, in accordance with certain embodiments, has a particle size distribution where 99% of the particles have a diameter less than 2 microns.

The secondary pigment may be a cationic pigment. It is added to the coating which, when fully assembled, typically has an overall anionic character. Attractive forces between the anionic coating and cationic pigment are believed to open up surface pores in the coating, increasing the porosity and the ink absorption rate. Ink drying times are also reduced. Additionally, since the ionic interaction is on a very small scale, the improved porosity is uniform over the coating surface. In one embodiment the particle size distribution of the secondary pigment has an average particle size less than about 3.0 microns and is grit-free. The term “grit-free” is intended to mean there are substantially no particles on a 325 mesh screen. Preferably, substantially all of the particles in the secondary pigment are sized at less than 1 micron. Amounts of the secondary pigment are limited to less than 20 parts based on 100 parts by weight of the total pigment. Use of excessive cationic component leads to undesirable ionic interaction and chemical reactions that change the nature of the coating. The secondary pigment is preferably present in amounts greater than 5 parts cationic pigment per 100 total parts pigment. Secondary pigments include carbonates, silicates, silicas, titanium dioxide, aluminum oxides and aluminum trihydrates. Preferred secondary pigments are cationics OMYAJET 6606 and OMYAJET 5010 pigments (OMYA AG, Oftringen, Switzerland), calcium carbonates. A cationic polymer may be used in place of or in combination with the secondary pigment.

The amount of cationic polymer used in the coating will depend on the charge density of the cationic polymer. In one embodiment the amount of the cationic polymer may be about 0.1 to 1.5 parts, preferably 0.2 to 1 part based on 100 parts total pigment. Examples of cationic polymers include polymeric quaternary ammonium compounds, such as poly(dimethylaminoethyl) methacrylate, polyalkylenepolyamines, and products of the condensation thereof with dicyanodiamide, amine-epichlorohydrin polycondensates, lecithin and phospholipid compounds. Examples of cationic pigments useful in the invention include vinylbenzyl trimethyl ammonium chloride/ethylene glycol dimethacrylate, vinylbenzyl trimethyl ammonium chloride/divinyl benzene, poly(diallyl dimethyl ammonium chloride), poly(2-N,N,N-trimethylammonium)ethyl methacrylate methosulfate, poly(3-N,N,N-trimethyl-ammonium)propyl methacrylate chloride, a copolymer of vinylpyrrolidinone and vinyl(N-methylimidazolium chloride, and hydroxyethyl cellulose derivitized with (3-N,N,N-trimethylammonium)propyl chloride. Cationic polymeric pigments useful in one embodiment of the invention can be derived from combinations of nonionic and cationic monomers. The nonionic or cationic monomers employed can include neutral or cationic derivatives of addition polymerizable monomers such as styrenes, alpha-alkylstyrenes, acrylate esters derived from alcohols or phenols, methacrylate esters (usually referred to as methacrylate), vinylimidazoles, vinylpyridines, vinylpyrrolidinones, acrylamides, methacrylamides, vinyl esters derived from straight chain and branched acids (e.g., vinyl acetate), vinyl ethers (e.g., vinyl methyl ether), vinyl nitriles, vinyl ketones, halogen-containing monomers such as vinyl chloride, and olefins, such as butadiene. The monomers employed can also include neutral or cationic derivatives of condensation polymerizable monomers such as those used to prepare polyesters, polyethers, polycarbonates, polyureas and polyurethanes.

Some specific examples of cationic polymers which may be used in the invention include those described in U.S. Pat. No. 3,958,995, hereby incorporated by reference in its entirety. Specific examples of these polymers include, for example, a terpolymer of styrene, (vinylbenzyl)dimethylbenzylamine and divinylbenzene (49.5:49.5:1.0 molar ratio); and a terpolymer of butyl acrylate, 2-aminoethylmethacrylate hydrochloride, hydroxyethylmethacrylate (50:20:30 molar ratio) and Nalkat 2020 (polydiallyl dimethyl ammoniumchloride).

Supplemental pigments are optional and may include anionic pigments and pigments used in the formulation as needed to improve coating properties as discussed below. In the case of calcium carbonate as a supplemental pigment, the average particle size of the calcium carbonate typically is about 1 to 5 microns, more particularly about 1.2 to 4 microns. In accordance with certain embodiments, the calcium carbonate used as a supplemental pigment may have a particle size distribution with a d98 of about 6 to 20 microns, more particularly about 8 to 17 microns. The one micron percentage may be about 10 to 50%, more particularly about 15 to 45%. Calcium carbonate supplemental pigments that are particularly useful may have a BET surface area in the range from about 2-4 m²/g more particularly about 2.5-3.5 m²/g. In addition to calcium carbonate, other representative examples of supplemental pigments are inorganic pigments such as titanium dioxide, clay etc. In one embodiment, up to an additional 50 parts by weight (or in another embodiment up to 35 parts by weight) of the dry coating pigment may be medium or coarse ground calcium carbonate, or TiO2, or mixtures thereof. An example of a ground calcium carbonate is Carbital 35 calcium carbonate (Imerys, Roswell, Ga.). Carbital 35 has an average particle size of 3.2 microns, d98 of 15 microns, a one micron percentage of 20%, and BET surface area of 3.5 m²/g. Another example is Hydrocarb 60 which has an average particle size of 1.4 microns, d98 of 8 microns (max.), a one micron percentage of 40%, and BET surface area of 7 m²/g. Another supplemental pigment is anionic titanium dioxide, such as that available from Itochu Chemicals America (White Plains, N.Y.).

In one embodiment a plastic pigment may be added to the coating up to about 15 parts. Hollow spheres are particularly useful plastic pigments for paper glossing. Examples of hollow sphere pigments include ROPAQUE 1353 and ROPAQUE AF-1055 (Rohm & Haas, Philadelphia, Pa.). Higher gloss papers are obtainable when fine pigments are used that have a small particle size. The relative amounts of the otional supplemental pigments and plastic pigment may vary depending on the desired coating viscosity, coating structure, whiteness and desired gloss levels.

A primary binder is added to the coating for adhesion. When a multivalent salt is present, the primary binder is compatible with the incorporation of the multivalent salt and the pigments in the coating formulation and typically is non-ionic. In accordance with certain embodiments, the binder may be a biopolymer such as a starch or protein. In accordance with particularly useful embodiments, the polymer may comprise biopolymer particles, more particularly biopolymer microparticles and in accordance with certain embodiments, biopolymer nanoparticles. In accordance with particularly useful aspects, the biopolymer particles comprise starch particles and, more particularly, starch nanoparticles having an average particle size of less than 400 nm. Compositions containing a biopolymer latex conjugate comprising a biopolymer-additive complex reacted with a crosslinking agent as described in WO 2010/065750 are particularly useful. Biopolymer-based binders and, in particular, those binders containing biopolymer particles have been found to be compatible with the inclusion of a multivalent salt in the coating formulation and facilitate coating production and processing. For example, in some cases coating compositions can be prepared at high solids while maintaining acceptable viscosity for the coating composition. Biopolymer binders that may find use in the present application are disclosed in U.S. Pat. Nos. 6,677,386; 6,825,252; 6,921,430; 7,285,586; and 7,452,592, and WO 2010/065750, the relevant disclosure in each of these documents is hereby incorporated by reference. One example of a suitable binder containing biopolymer nanoparticles is Ecosphere ®2240 available from Ecosynthetix Inc.

The binder may also be a synthetic polymeric binder. In accordance with certain embodiments, the binder may be a non-ionic synthetic latex such as an acrylate or an acrylate copolymer. In accordance with other embodiments, the binder may be a vinyl acetate or a styrene butadiene latex. In one embodiment in which the coating includes a polyvalent metal salt, a calcium stable latex is used.

The binder may also be a synthetic polymeric binder such as polyvinyl alcohol, polyvinyl pyrrolidone, polyethylene oxide, acrylates, polyurethanes, etc.

The total amount of primary binder in one embodiment is up to about 17% per 100 parts of total pigments. In another embodiment the binder is present in an amount from about 2 to about 15, more particularly about 5 to about 12, parts per 100 parts of total pigments. In accordance with certain embodiments, a binder containing biopolymer particles may be the only binder in the coating composition. In one embodiment, the binder is styrene butadiene latex. This coating is disclosed in more detail in U.S. Pat. No. 7,803,224 cited above. In another embodiment it is a calcium stable anionic synthetic styrene butadiene latex binder.

In another embodiment, the coating may also include a co-binder that is used in addition to the primary binder. Examples of useful co-binders include polyvinyl alcohol and protein binders. The co-binder, when present, typically is used in amounts of about 1 to about 8 parts co-binder per 100 parts of pigment on a dry weight basis, more particularly from about 2 to 5 parts co-binder per 100 parts dry pigment. Another co-binder that is useful in some embodiments is starch. Both cationic and anionic starches may be used as a co-binder. ADM Clineo 716 starch is an ethylated cornstarch (Archer Daniels Midland, Clinton, Iowa). Penford PG 260 is an example of another starch co-binder that can be used. If a cationic co-binder is used, the amount used typically is limited so that the overall anionic nature of the coating is maintained. The binder levels should be carefully controlled. If too little binder is used, the coating structure may lack physical integrity, while if too much binder is used, the coating may become less porous resulting in longer ink drying times.

In accordance with some embodiments, the coating is substantially free (for example, no more than 0.2 parts) of any SBR latex binder that is not calcium stable.

In one embodiment the coating composition may also include a multivalent salt. In certain embodiments of the invention, the multivalent metal is a divalent or trivalent cation. More particularly, the multivalent metal salt may be a cation selected from Mg⁺², Ca⁺², Ba⁺², Zn⁺², and Al⁺³, in combination with suitable counter ions. Divalent cations such as Ca⁺² and Mg⁺² are particularly useful. Combinations of cations may also be used.

Specific examples of the salt used in the coating include (but are not limited to) calcium chloride, calcium acetate, calcium nitrate, magnesium chloride, magnesium acetate, magnesium nitrate, magnesium sulfate, barium chloride, barium nitrate, zinc chloride, zinc nitrate, aluminum chloride, aluminum hydroxychloride, and aluminum nitrate. Similar salts will be appreciated by the skilled artisan. Particularly useful salts include CaCl₂, MgCl₂, MgSO₄, Ca(NO₃)₂, and Mg(NO₃)₂, including hydrated versions of these salts. Combinations of the salts may also be used. The salt may be present in the coating in an amount of about 2.5 to 25 parts, more particularly about 4 to 12.5 parts by weight based per 100 total parts of pigment.

A water retention aid may also be included in the coating to improve water retention. Coatings containing multivalent ions can lack sufficient water holding capability for commercial applications. In addition to increasing water retention, a secondary advantage is that it unexpectedly enhances the binding strength of the biopolymer. Tape pulls indicate better strength in coating formulations including a retention aid. Examples of water retention aids for use herein include, but are not limited to, polyethylene oxide, hydroxyethyl cellulose, polyvinyl alcohol, starches, and other commercially available products sold for such applications. One specific example of a suitable retention aid is Natrasol GR (Aqualon). In accordance with certain embodiments, the water retention aid is present in an amount of about 0.1 to 2 parts, more particularly about 0.2 to 1 part per 100 parts of total pigments.

In accordance with some aspects, the coating composition may contain a dispersant that enables the composition to be formulated at a high solids content and yet maintain an acceptable viscosity. However, due to the particular components utilized to prepare the high solids coatings, typically used dispersants may not be suitable because they may lead to unacceptable viscosities. Examples of dispersants include Topsperse™ JX A (Polyether polycarboxylate, sodium salt in aqueous solution), Topsperse™ TSA, Rheocarb™ 100 (Acrylic copolymer in aqueous solution), polyoxyalkylene sodium salt (Carbosperse™. K-XP228 polymer), and XP-1722 (Polyether polycarboxylate, sodium salt in aqueous solution) from Coatex, BYK-190 (Solution of a high molecular weight block copolymer with pigment affinic groups) and BYK-2010 (Acrylate copolymer with pigment affinic groups) from BYK Chemie, Polystep®TD-507 (Tridecyl alcohol ethoxylate) from Stepan Chemicals, and Carbosperse™ K-XP228 (Polyoxyalkylene sodium salt) from Lubrizol.

The dispersant (e.g., Topsperse JXA) may be present in an amount of 0 to about 4 parts. When the dispersant is present it is present in an amount of about 0.5 to 3 part, more particularly about 0.75 to 2.5 parts per 100 parts of total pigments. One class of dispersants that have been found to be suitable in certain embodiments include dispersants containing polymers with pigment affinic groups, polyether polycarboxylate salts and polyoxyalkylene salts.

Other optional additives may be used to vary properties of the coating. Brightening agents, such as Clariant T26 Optical Brightening Agent, (Clariant Corporation, McHenry, Ill.) can be used. Insolubilizers or cross-linkers may be useful. A particularly useful cross-linker is Sequarez 755 (RohmNova, Akron, Ohio). A lubricant is optionally added to reduce drag when the coating is applied with a blade coater. Diglyceride lubricants are particularly useful in accordance with certain embodiments. These optional additives, when present, are typically present in an amount of about 0.1 to 5 parts, more particularly about 0.2 to 2 parts per 100 parts of total pigments.

Conventional mixing techniques may be used in making this coating. If starch is used, it typically is cooked prior to preparing the coating using a starch cooker. In accordance with certain embodiments, the starch may be made down to approximately 35% solids. Separately, all of the pigments, including the primary pigment, secondary and any supplemental pigments, may be mixed for several minutes to ensure no settling has occurred. In the laboratory, the pigments may be mixed on a drill press mixer using a paddle mixer. The primary binder is then added to the mixer, followed by the co-binder 1-2 minutes later. If starch is used, it is typically added to the mixer while it is still warm from the cooker, approximately 190° F. The final coating is made by dispersion of the mixed components in water. Solids content of the dispersion typically is from about 35% to about 65% by weight. More particularly, the solids may be about 45% to about 60% of the dispersion by weight.

The ink receptive coating may be supercalendared in one embodiment of the invention. In one embodiment, the sheets were supercalendared at 1200 pli, 100° F., 25 feet per minute and 3 nips.

Yet another embodiment relates to an improved printing paper for applying an electrically conductive ink having a paper substrate to which the coating has been applied on at least one surface. Any coating method or apparatus may be used, including, but not limited to, roll coaters, jet coaters, blade coaters or rod coaters. The coating weight is typically about 2 to about 10, more particularly about 5 to about 8, pounds per 3300 ft.² per side, to size press, pre-coated or unsized base papers. Coated papers would typically range from about 30 lb. to about 250 lb./3300 ft.² of paper surface. The coated paper is then optionally finished using conventional methods to the desired gloss.

The substrate or base sheet may be a conventional base sheet. Examples of useful base sheets include, Newpage 45 lb, Pub Matte, NewPage 45 lb New Era, NewPage 60 lb. Web Offset base paper, Orion, and NewPage 105 lb. Satin Return Card Base Stock, both from NewPage Corporation (Wisconsin Rapids, Wis.).

The finished coated paper is useful for application of electrically conductive inks Ink is applied to the coating to create a circuit. In one embodiment, depending on the nature of the ink, after application, the ink vehicle penetrates the coating and is absorbed therein. The number and uniformity of the coating pores result in even and rapid ink absorption, even when multiple layers of ink are applied. This coated paper may also be well suited for multifunctional printing, whereby an image on a coated paper media is created from combinations of dyes or pigmented inks from ink jet printers, toner from laser printers and inks from gravure or flexo presses.

The following non-limiting examples illustrate specific aspects of the present invention.

### EXAMPLE 1

Coatings were prepared from the components of Table I. A40 is an anionic, precipitated aragonite, Opacarb A40 by Specialty Minerals, and serves as the primary pigment. The secondary pigment is OMYAJET 6606. AF 1055 refers to the plastic pigment by RohmNova, Akron, Ohio. C35 is an anionic, course CaCO₃ available from Imerys Minerals Ltd., Cornwall, England. It is a supplemental pigment. The three latex polymer binders tested are Genflo 5915 styrene/butadiene latex (“5915 SBR”), Gencryl 9750 acrylonitrile latex (“9750”I″) and Genflo 5086 styrene/butadien“(″5086”BR″) latex discussed above. The type and amount of latex tested is shown in Table I. ADM 716 refers to Clineo 71“(″ADM”16″) cornstarch by Archer Daniels Midland, a co-binder. Sequarez 755 is a crosslinker available from RohmNova, Akron, Ohio. Clariant T 26 OB“(″T26”BA″) is an optical brightener by Clariant Corporation, McHenry, Ill. The ADM 716 starch was cooked and the coating prepared as described above.

TABLE 1
Composition of Coating Samples

| Component | 60231 | 70012 | 70013 | 70014 | 70015 | 70016 | 70017 | 70018 | 70019 |
|---|---|---|---|---|---|---|---|---|---|
| A40 | 70 | 70 | 70 | 70 | 70 | 70 | 70 | 70 | 70 |
| AF 1055 | 8 | 8 | 8 | 8 | 8 | 8 | 8 | 8 | 8 |
| TiO₂ | 7 | 7 | 7 | 7 | 7 | 7 | 7 | 7 | 7 |
| Omyajet B | 15 | 0 | 0 | 0 | 0 | 0 | 15 | 15 | 0 |
| C35 | 0 | 15 | 15 | 15 | 15 | 15 | 0 | 0 | 15 |
| 5915 SBR | 14.5 | 13.5 | 15.5 | 0 | 0 | 0 | 0 | 0 | 0 |
| 9750 ACN | 0 | 0 | 0 | 0 | 13.5 | 15.5 | 15.5 | 17.5 | 13.3 |
| 5086 SBR | 0 | 0 | 0 | 15.5 | 0 | 0 | 0 | 0 | 0 |
| ADM 716 | 4 | 4 | 4 | 4 | 4 | 4 | 4 | 4 | 4 |
| Sequarez 755 | 0.5 | 0.5 | 0.5 | 0.5 | 0.5 | 0.5 | 0.5 | 0.5 | 0.5 |
| T26 OBA | 3 | 3 | 3 | 3 | 3 | 3 | 3 | 3 | 3 |

### EXAMPLE 2

OMYAJET 6606 pigment is normally sold as cationic. Upon request, a sample was prepared by the manufacturer exactly like OMYAJET 6606 pigment, except in an anionic form. Coatings were made from both the anionic and cationic forms of OMYAJET 6606 pigment to determine if the ionic charge had a significant effect on the coating performance. The coating formulations are shown in Table 2. The coating weight is shown in Table 3.

TABLE 2

| Component | 060230 | 060231 |
|---|---|---|
| HF 90 Clay | 0 | 0 |
| Plastic Pigment | 8 | 8 |
| TiO₂ | 7 | 7 |
| A40 Aragonite | 70 | 70 |
| OMYA B Anionic | 15 | 0 |
| OMYA B Cationic | 0 | 15 |
| SB Latex | 14.5 | 14.5 |
| Starch | 4 | 4 |
| OBA | 3 | 3 |

TABLE 3

| Component | 060230 | 060231 |
|---|---|---|
| Coal Weight | 6.5 | 6.5 |
| Basis Weight | 54.28 | 53.21 |

Representative coating compositions include those shown in Table 4 below.

TABLE 4
Non-limiting Coating Formulation Ranges

| | Range (A) | Range (B) | |
|---|---|---|---|
| | Dry Parts | Dry Parts | |
| Generic Material | (approx) | (approx) | Example Material |
| Supplemental Pigment | 0-50 | 5-40 | Coarse Carbonate |
| | | | Carbital 35, TiO2 |
| Secondary Pigment | 0-20 | 5-12.5 | OMYAJET 6606; |
| | | | Omyajet 5010, |
| Primary Binder | 2-15 | 5-12 | Ecosphere, SB latex |
| Co-binder | 0-10 | 2-7.5 | Starch |
| Salt | 0-25 | 0-12.5 | Calcium Chloride |
| Plastic Pigment | 0-15 | 5-12.5 | Ropaque AF-1353 |
| Primary Pigment | 35-100 | 40-90 | Argonite (Opacarb A- |
| | | | 40),Fine Ground |
| | | | calcium chloride |
| | | | (Hydrocarb HP) |
| Crosslinker | 0-1 | 0.25-0.7 | Sequarez 755 |
| Lubricant | 0-1 | 0.4-0.8 | Berchem 4113 |
| Water Retention aid | 0-2 | 0.2-1 | Hydroxyethyl cellulose |
| Cationic Polymer | 0-1.5 | 0.2-1 | Nalkat 2020 |
| Dispersant | 0-4 | 0-3 | Topsperse ™ JX A |

Having described the invention in detail and by reference to specific embodiments thereof, numerous variations and modifications are possible without departing from the spirit and scope of the following claims.

What is claimed is:

1. A printed electronic device comprising:
a paper substrate; and
an ink jet-receptive coating including a primary pigment;
a member selected from the group consisting of a secondary pigment, a polyvalent metal salt, a cationic polymer, or mixtures thereof; and
a binder wherein said binder is present in an amount from about 2 to 15 parts by weight per 100 parts total pigments; and
an electronically conductive ink printed on the ink jet-receptive coating in the form of an electronic circuit.

2. The printed electronic device of claim 1 wherein the binder comprises a synthetic latex or water soluble polymer.

3. The printed electronic device of claim 2 wherein the binder is styrene-butadiene latex.

4. The printed electronic device of claim 3 wherein the coating contains a multivalent salt and a calcium stable styrene butadiene latex.

5. The printed electronic device of claim 2 wherein said binder further comprises starch nanoparticles.

6. The printed electronic device of claim 5 wherein said binder comprises a biopolymer latex conjugate comprising a biopolymer-additive complex reacted with a crosslinking agent.

7. The printed electronic device of claim 1 wherein said primary pigment comprises calcium carbonate.

8. The printed electronic device of claim 7 wherein the primary pigment comprises aragonite or fine ground calcium carbonate.

9. The printed electronic device of claim 1 further comprising at least one secondary pigment selected from the group consisting of cationic calcium carbonate.

10. The printed electronic device of claim 1 wherein said coating further comprises a co-binder selected from the group consisting of protein binders, polyvinyl alcohol, starch and mixtures thereof.

11. The printed electronic device of claim 1 wherein said primary pigment is present in an amount of about 35 to 100 parts based on 100 parts total pigments.

12. The printed electronic device of claim 13 wherein said coating further comprises a plastic pigment present in an amount of about 2 to 15 parts per 100 parts total pigments.

13. The printed electronic device of claim 1 wherein said coating is present at a coat weight of about 2 to 8 lbs./ream (3,300 ft.²).

14. The printed electronic device of claim 1 wherein the ink-receptive coating does not include a polyvalent salt.

15. The printed electronic device of claim 1 wherein said binder comprises starch.

16. The printed electronic device of claim 1 wherein the electrically conductive ink comprises a copper, aluminum, or silver pigment.

17. The printed electronic device of claim 1 comprising a primary pigment having an average particle size of less than 1 micron; a secondary pigment having an average particle size of about 3 to 5 microns; and a binder wherein said binder is present in an amount from about 2 to 15 parts by weight per 100 parts total pigments.

18. The printed electronic device of claim 1 wherein the ink jet receptive coating contains a cationic polymer

19. The printed electronic device of claim 18 wherein the cationic polymer includes poly(diallyl dimethyl ammonium chloride).

20. A method for forming an electronic device which comprises applying a pattern of a conductive ink to the surface of an ink-receptive coating which comprises a primary pigment; a secondary pigment; and a binder wherein said binder is present in an amount from about 2 to 15 parts by weight per 100 parts total pigments.
